(19) United States
(12) Patent Application Publication
(10) Pub. No.: US 2026/0101799 A1
(43) Pub. Date: Apr. 9, 2026

(54) SEMICONDUCTOR STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: LI-WEN HO, HSINCHU CITY (TW); CHUNG-CHUAN TSENG, HSINCHU CITY (TW)

(21) Appl. No.: 18/906,717

(22) Filed: Oct. 4, 2024

(51) Int. Cl. H01L 23/00

(52) U.S. Cl. CPC H10W 72/90; H10W 72/019; H10W 72/01931; H10W 72/01951; H10W 72/932

(57) ABSTRACT

A semiconductor structure includes a first conductive element having a first side, a second conductive element having a second side contacting the first side of the first conductive element; and a blocking member, surrounded by the first conductive element and adjacent to the second conductive element. A first width of the first side is substantially greater than a second width of the second side, and at least a portion of the first conductive element is disposed between the second conductive element and the blocking member. A method of manufacturing a semiconductor structure, includes providing a dielectric; patterning the dielectric to form a first opening having a first portion and a second portion connected to the first portion, wherein a blocking member is disposed within the first portion; disposing a first conductive element and a second conductive element into the first portion and the second portion of the first opening respectively.

### BACKGROUND

The semiconductor industry has experienced rapid growth due to ongoing improvements in the integration density of a variety of components, such as photoelectric devices, electrical components, and others. To accommodate the miniaturized scale of semiconductor structures, an integrated circuit contains a plurality of patterns of metal lines separated by inter-wiring spacings and a plurality of interconnect lines, such as bus lines, bit lines, word lines and logic interconnect lines.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic top view of a semiconductor structure in accordance with some embodiments of the present disclosure.

FIG. 2 is a cross-sectional view of a semiconductor structure in accordance with some embodiments of the present disclosure.

FIG. 3 is a cross-sectional view of a semiconductor structure in accordance with some embodiments of the present disclosure.

FIGS. 3A and 3B are cross-sectional views of a semiconductor structure in accordance with some embodiments of the present disclosure.

FIGS. 4 to 11 are schematic top views of semiconductor structures in accordance with some embodiments of the present disclosure.

FIG. 12 is a flow diagram of a method of manufacturing a semiconductor structure in accordance with some embodiments of the present disclosure.

FIGS. 13A, 14A, 15A and 16A are schematic top views of one or more stages of the method of manufacturing a semiconductor structure in accordance with some embodiments of the present disclosure.

FIGS. 13B, 14B, 14C, 15B, 15C, 16B and 16C are schematic cross-sectional views of one or more stages of the method of manufacturing a semiconductor structure in accordance with some embodiments of the present disclosure.

FIG. 17 is a flow diagram of a method of manufacturing a semiconductor structure in accordance with some embodiments of the present disclosure.

FIGS. 18A, 19A, 20A, 21A, 22A, 23A, and 24A are schematic top views of one or more stages of the method of manufacturing a semiconductor structure in accordance with some embodiments of the present disclosure.

FIGS. 18B, 19B, 20B, 21B, 22B, 22C, 23B, 23C, 24B, and 24C are schematic cross-sectional views of one or more stages of the method of manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies.

Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

As the demand for shrinking electronic devices has grown, a need for smaller and more reliable metal layouts of semiconductor structures has emerged. An example of commonly used methods for forming metal lines is a process which involves forming an opening in a dielectric interlayer. The opening is typically formed using related lithographic and etching techniques. After the opening is formed, the opening is filled with metal or metal alloys, such as copper or copper alloys, to form a metallization layer. Excess metal material on a surface of the dielectric interlayer is then removed by chemical mechanical polishing (CMP). Although use of copper in the metallization layer offers a benefit of lower resistivity, copper suffers from electro-migration (EM) and stress-migration (SM) reliability issues as geometries continue to shrink and current densities increase.

In the present disclosure, a semiconductor structure and a method of manufacturing a semiconductor structure are provided. A semiconductor device includes a first conductive element, a second conductive element electrically coupled to the first conductive element, a first blocking member surrounded by the first conductive element, and a dielectric layer surrounding the first conductive element and the second conductive element.

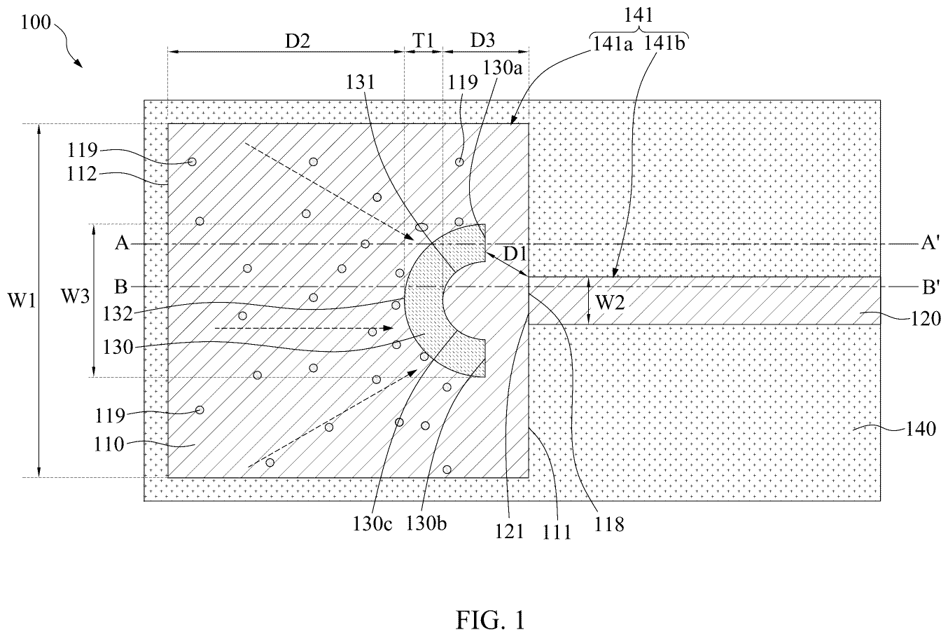

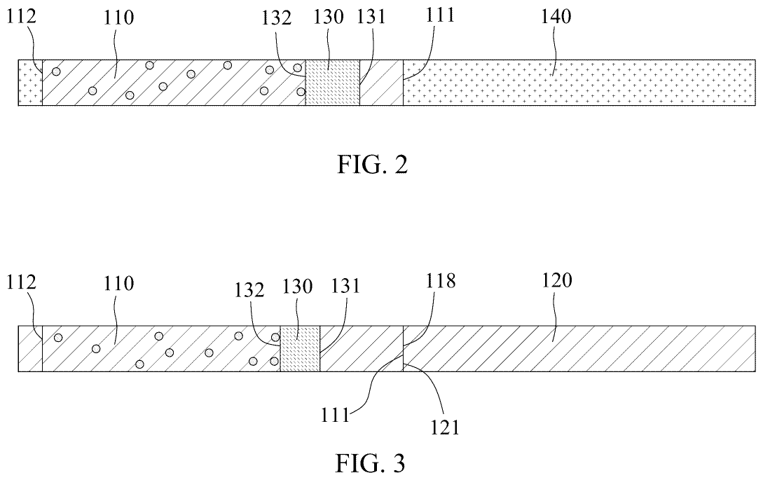

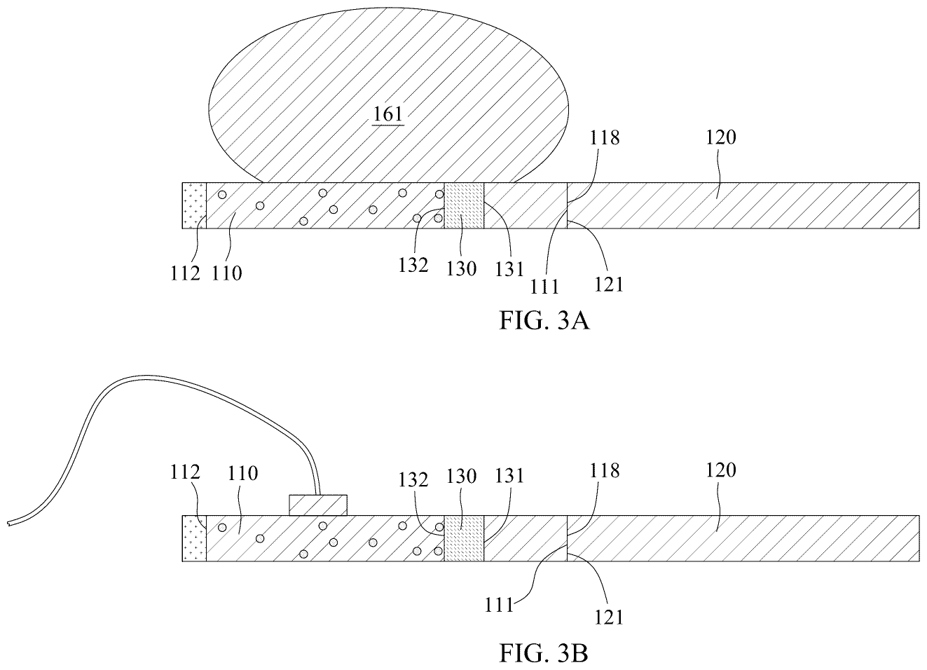

FIG. 1 is a schematic top view illustrating a semiconductor structure according to aspects of the present disclosure in some embodiments. FIG. 2 is a schematic cross-sectional view taken along a line A-A′ in FIG. 1. FIG. 3 is a schematic cross-sectional view taken along a line B-B′ in FIG. 1.

Referring to FIGS. 1, 2 and 3, the semiconductor structure 100 includes a first conductive element 110, a second conductive element 120 attached to the first conductive element 110, a first blocking member 130 surrounded by the first conductive element 110, and a dielectric layer 140 surrounding the first conductive element 110 and the second conductive element 120. FIGS. 1, 2 and 3 illustrate only the first conductive element 110 and the second conductive element 120 for clarity and simplicity, but such example is intended to be illustrative only, and is not intended to be limiting to the embodiments. A person ordinarily skilled in the art would readily understand that any suitable number of the first conductive element 110 and the second conductive element 120 may alternatively be utilized, and all such combinations are intended to be fully included within the scope of the embodiments.

In some embodiments, the first conductive element 110 includes a first conductive material. In some embodiments, the first conductive material is deposited in a first portion 141a of an opening 141 of the dielectric layer 140 and is electrically connected to the second conductive element 120. The first conductive material may be deposited by chemical vapor deposition (CVD) or plating, such as electroplating or electroless plating, or the like. The first conductive material may comprise metal, such as copper, titanium, tungsten, aluminum, or the like. In some embodiments, some voids 119 are disposed in the first conductive element 110 due to a formation process of the first conductive element 110.

In some embodiments, the second conductive element 120 includes a second conductive material. In some embodiments, the second conductive material is deposited in a second portion 141b of the opening 141 of the dielectric layer 140 and is electrically connected to the first conductive element 110. The second conductive material may be deposited by CVD or plating, such as electroplating or electroless plating, or the like. The second conductive material may comprise metal, such as copper, titanium, tungsten, aluminum, or the like. In some embodiments, the second conductive material is similar to or different from the first conductive material. In some embodiments, the first conductive material and the second conductive material have a same composition.

In some embodiments, each of the first conductive element 110 and the second conductive element 120 are quadrilateral from a top view perspective. The first conductive element 110 and the second conductive element 120 can be, but are not limited to, round, oval, rectangular, square or another desired shape. In some embodiments, opposing edges of the first conductive element 110 are either parallel to or perpendicular to longitudinal edges of the second conductive element 120. In some embodiments, the first conductive element 110 is a metal pad and the second conductive element 120 is a metal line or a bit line.

In some embodiments, the first conductive element 110 has a first side 111, and the second conductive element 120 has a second side 121 contacting the first side 111 of the first conductive element 110. The first side 111 attaches to the second side 121, and the first conductive element 110 is mechanically and electrically coupled to the second conductive element 120. In some embodiments, a first width W1 of the first side 111 is substantially greater than a second width W2 of the second side 121. In some embodiments, the first width W1 is at least 20 times the second width W2.

In some embodiments, when power is applied to the semiconductor structure 100, and current flows from the first conductive element 110 to the second conductive element 120, voids 119 in the first conductive element 110, if any, move toward the second conductive element 120. Due to a size difference between the first conductive element 110 and the second conductive element 120, when too many voids 119 gather at an interface 118 between the first conductive element 110 and the second conductive element 120, the first conductive element 110 and the second conductive element 120 may be disconnected, causing the semiconductor structure 100 to short-circuit.

In some embodiments, the first conductive element 110 and the second conductive element 120 are laterally encapsulated by the dielectric layer 140. In some embodiments, the dielectric layer 140 may include a polymer such as PBO, polyimide, BCB, or the like; a nitride such as silicon nitride; an oxide such as silicon oxide, PSG, BSG, BPSG or the like; or a combination thereof. In some embodiments, the dielectric layer 140 may be formed, for example, by any acceptable deposition process, such as spin coating, CVD, laminating, the like, or a combination thereof.

The first blocking member 130 is surrounded by the first conductive element 110 and is adjacent to the second conductive element 120. In some embodiments, the first blocking member 130 is configured to prevent the voids 119 from gathering at the interface 118 between the first conductive element 110 and the second conductive element 120, and therefore may prevent the short-circuiting of the semiconductor structure 100. In some embodiments, the first blocking member 130 has a top surface substantially coplanar with a top surface of the first conductive element 110, as shown in FIGS. 2 and 3.

In some embodiments, in order to ensure electrical coupling between the first conductive element 110 and the second conductive element 120, at least a portion of the first conductive element 110 is disposed between the second conductive element 120 and the first blocking member 130. In some embodiments, the first conductive element 110 has a third side 112 opposite to the first side 111. The third side 112 is distal from the second conductive element 120. In some embodiments, a first distance D1 between the second side 121 and the first blocking member 130 is substantially less than a second distance D2 between the third side 112 and the first blocking member 130. In some embodiments, the first distance D1 is substantially greater than 50 nm. In some embodiments, the first distance D1 is also the distance between the first blocking member 130 and the interface 118.

In some embodiments, the first blocking member 130 has a third width W3 substantially greater than the second width W2 of the second conductive element 120. The first blocking member 130 having the third width W3 greater than the second width W2 of the second conductive element 120 may successfully prevent the voids 119 from moving to the interface 118. In some embodiments, the first blocking member 130 has a first thickness T1 substantially greater than 50 nm. In some embodiments, the first thickness T1 is constant.

The first blocking member 130 may be designed in various shapes or formations. In some embodiments, the first blocking member 130 is designed to be C-shaped in order to prevent the voids 119 from approaching the interface 118. Meanwhile, a circuit path between the first conductive element 110 and the second conductive element 120 must be preserved, so a position of the first blocking member 130 must be carefully designed. In some embodiments, the first blocking member 130 includes a first concave portion 131 facing the second side 121 of the second conductive element 120. In some embodiments, the first concave portion 131 faces the interface 118. In some embodiments, the blocking member 130 further includes a first convex portion 132 disposed opposite to the first concave portion 131.

In some embodiments, the first blocking member 130 has two opposite ends 130a and 130b, and a middle portion 130c disposed between the two opposite ends 130a and 130b from a top view perspective. In some embodiments, the first distance D1 equals a distance between one of the two ends 130a, 130b of the first blocking member 130 and the second side 121 of the second conductive element 120. A third distance D3 between the middle portion 130c and the second side 121 of the second conductive element 120 is substantially greater than the first distance D1. In some embodiments, in comparison with the two opposite ends 130a, 130b of the first blocking member 130, the middle portion 130c of the first blocking member 130 is disposed farther away from the second side 121 of the second conductive element 120. In some embodiments, the first blocking member 130 is arc-shaped from a top view perspective. In some embodiments, the first blocking member 130 is C-shaped or U-shaped from a top view perspective. In some embodiments, the first blocking member 130 is continuous and integral.

In some embodiments, the first blocking member 130 includes dielectric material. In some embodiments, the first blocking member 130 may include a polymer such as PBO, polyimide, BCB, or the like; a nitride such as silicon nitride; an oxide such as silicon oxide, PSG, BSG, BPSG or the like; or a combination thereof. In some embodiments, the first blocking member 130 and the dielectric layer 140 include a same dielectric material. In some embodiments, the first blocking member 130 and the dielectric layer 140 include different dielectric materials.

In some embodiments, the semiconductor structure 100 including the first conductive element 110, the second conductive element 120, the first blocking member 130 and the dielectric layer 140 is configured in a redistribution layer (RDL) of a semiconductor device or a semiconductor package. In some embodiments, the first conductive element 110 and the second conductive element 120 are a metal layout or a part of a metal layout of the RDL. In some embodiments, the dielectric layer 140 is an isolation or a part of an isolation of the RDL.

FIGS. 3A and 3B are cross-sectional views of a semiconductor structure in accordance with some embodiments of the present disclosure. In some embodiments, the first conductive element 110 is a bump pad, a die pad, a pillar pad, a bonding pad, or a metal pad formed during BEOL process, etc., and the second conductive element 120 is a conductive line electrically connected with the first conductive element 110. In some embodiments, referring to FIG. 3A, the first conductive element 110 is a bump pad, and a bump 161 is disposed on and electrically connected to the first conductive element 110. In some embodiments, the bump 161 is a solder ball, a metallic pillar or the like. In some embodiments, the bump 161 partially or entirely cover the first blocking member 130. In some embodiments, the first blocking member 130 is in contact with the bump 161. In some embodiments, referring to FIG. 3B, the first conductive element 110 is a wire bonding pad, and a bond wire 162 is attached and electrically connected to the first conductive element 110.

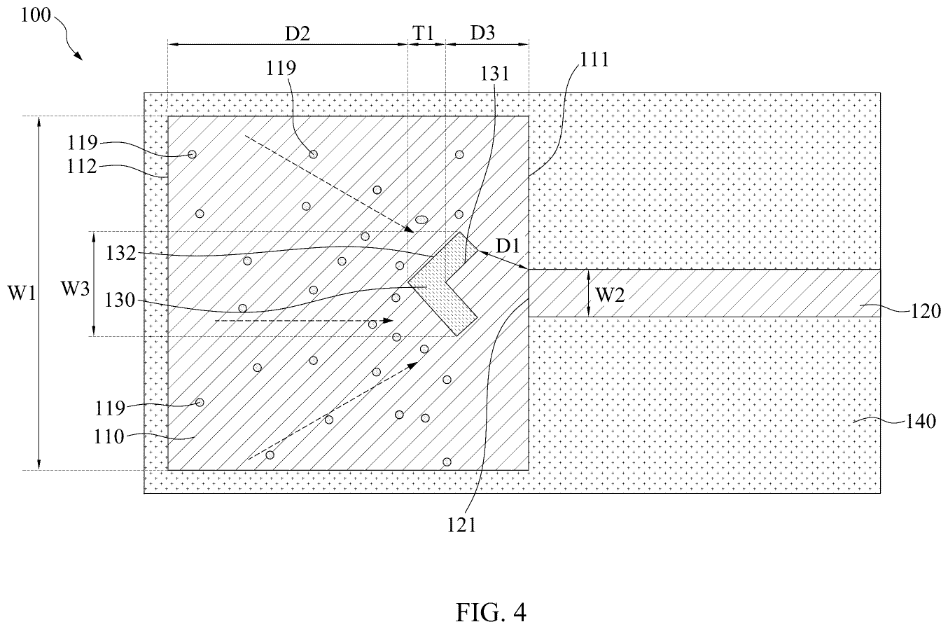

FIG. 4 is a schematic top view illustrating a semiconductor structure according to aspects of the present disclosure in some embodiments. In some embodiments, referring to FIG. 4, a first blocking member 130 is L-shaped with a concave portion 131 facing a second side 121 of a second conductive element 120 from a top view perspective.

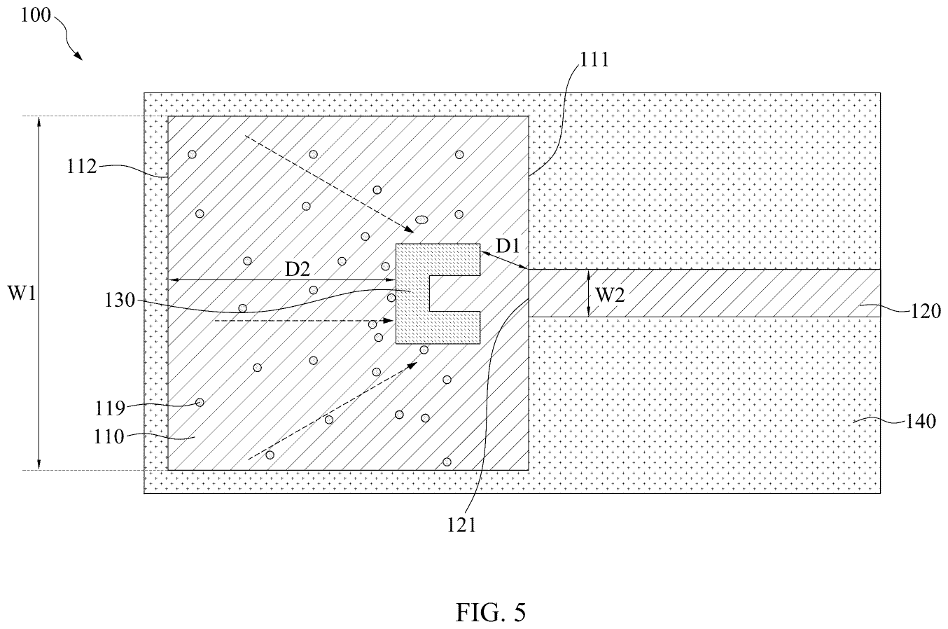

FIG. 5 is a schematic top view illustrating a semiconductor structure according to aspects of the present disclosure in some embodiments. In some embodiments, referring to FIG. 5, a first blocking member 130 is C-shaped with a first concave portion 131 facing a second side 121 of a second conductive element 120 from a top view perspective.

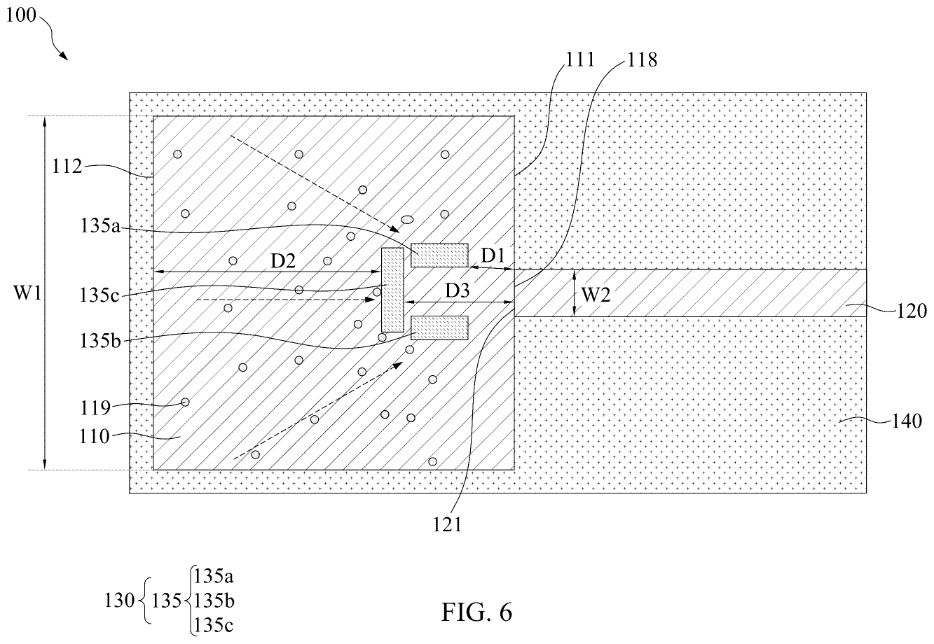

FIG. 6 is a schematic top view illustrating a semiconductor structure according to aspects of the present disclosure in some embodiments. In some embodiments, referring to FIG. 6, a first blocking member 130 includes segments 135 separated from each other. In some embodiments, the first blocking member 130 includes the segments 135, and adjacent segments 135 are in contact with each other.

In some embodiments, the first blocking member 130 includes a first segment 135a, a second segment 135b and a third segment 135c. In some embodiments, the first blocking member 130 includes a first concave portion 131 formed by an arrangement of the first segment 135a, the second segment 135b and the third segment 135c. In some embodiments, the arrangement of the first segment 135a and the second segment 135b defines a third width W3 of the first blocking member 130. In some embodiments, the third segment 135c is disposed adjacent to or between the first segment 135a and the second segment 135b. In some embodiments, a third distance D3 is a distance between the third segment 135c and an interface 118.

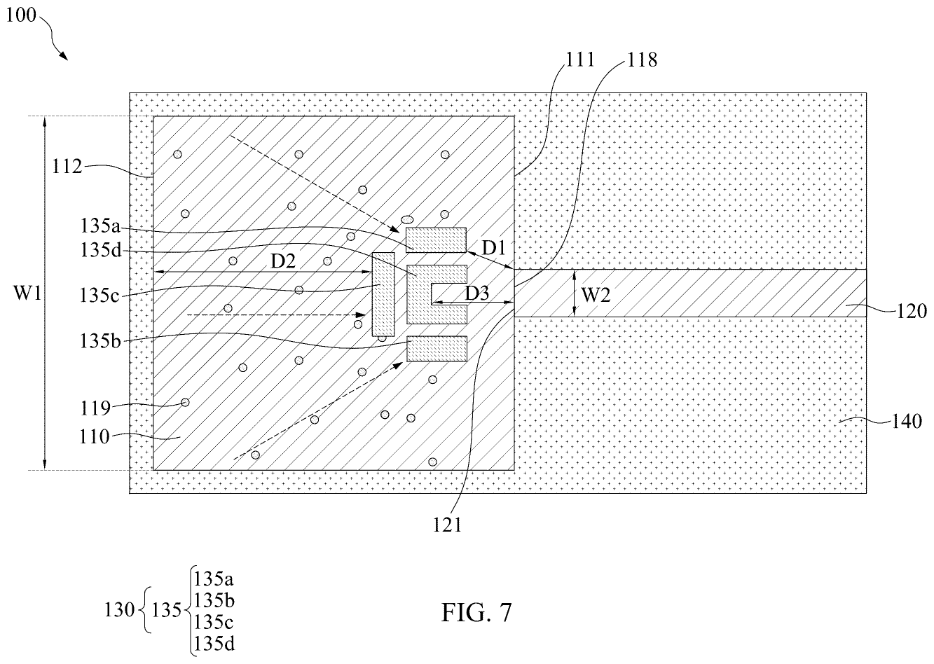

FIG. 7 is a schematic top view illustrating a semiconductor structure according to aspects of the present disclosure in some embodiments. In some embodiments, referring to FIG. 7, a first blocking member 130 includes multilayers of segments 135, wherein segments 135 are separated from each other. In some embodiments, the first blocking member 130 includes a first segment 135a, a second segment 135b, a third segment 135c, a fourth segment 135d disposed between the first segment 135a and the second segment 135b. In some embodiments, a first concave portion 131 of the first blocking member 130 is formed by an arrangement of the segments 135. In some embodiments, the fourth segment 135d is disposed between the third segment 135c and a second side 121 of a second conductive element 120. In some embodiments, a third distance D3 is a distance between the fourth segment 135d and an interface 118.

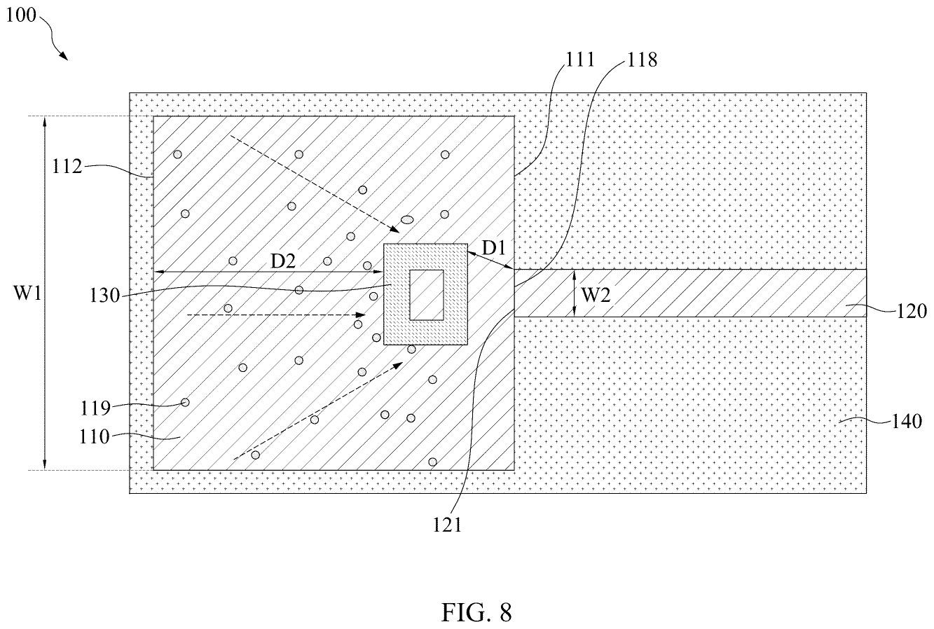

FIG. 8 is a schematic top view illustrating a semiconductor structure according to aspects of the present disclosure in some embodiments. In some embodiments, referring to FIG. 8, a first blocking member 130 is in a shape of a frame or a ring from a top view perspective. In some embodiments, the first blocking member 130 has no first concave portion 131, and only includes a first convex portion 132. In some embodiments, a portion of a first conductive element 110 is surrounded by the first blocking member 130.

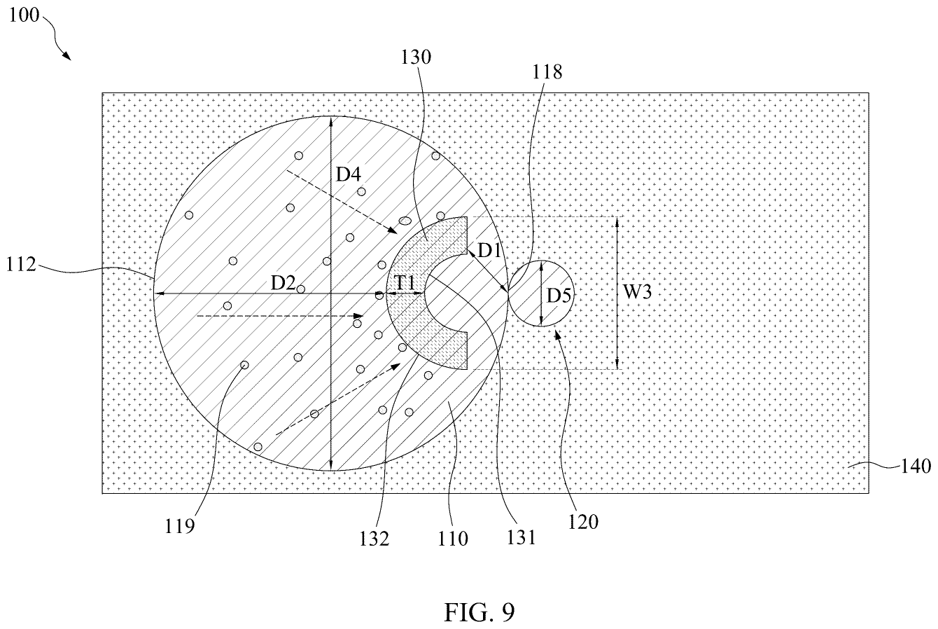

FIG. 9 is a schematic top view illustrating a semiconductor structure according to aspects of the present disclosure in some embodiments. In some embodiments, referring to FIG. 9, a first conductive element 110 and a second conductive element 120 have round shapes from a top view perspective. In some embodiments, a diameter D4 of the first conductive element 110 is substantially greater than a diameter D5 of the second conductive element 120. In some embodiments, the diameter D4 of the first conductive element 110 is at least twice the diameter D5 of the second conductive element 120. In some embodiments, a third width W3 of a first blocking member 130 is equal to or substantially greater than a diameter D5 of the second conductive element 120.

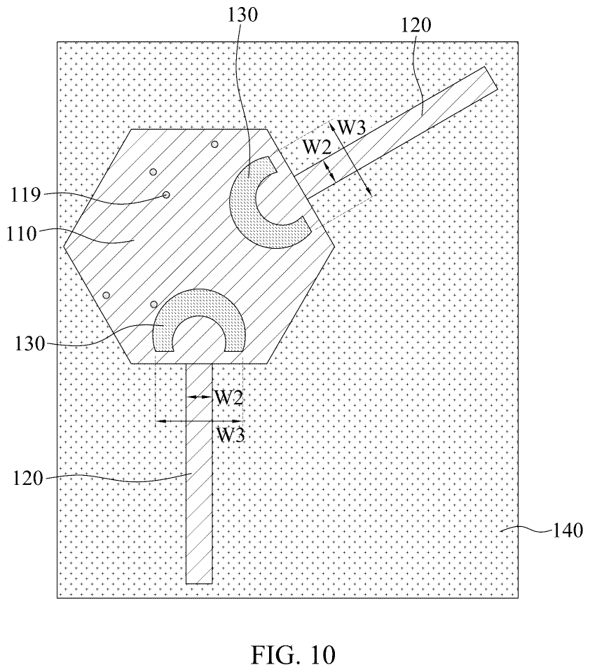

FIG. 10 is a schematic top view illustrating a semiconductor structure according to aspects of the present disclosure in some embodiments. In some embodiments, referring to FIG. 10, a plurality of first blocking members 130 are surrounded by a first conductive element 110. In some embodiments, a plurality of second conductive elements 120 are electrically coupled to the first conductive element 110. A number of the first blocking members 130 may be adjusted according to a number of the second conductive elements 120. In some embodiments, the first conductive element 110 is in a shape of a polygon, each of the second conductive elements 120 is coupled to a different side of the first conductive element 110, and each of the first blocking members 130 faces a different second conductive element 120. Dimensions, configurations and materials of the first blocking members 130 may be similar to or different from each other, and configurations and materials of the second conductive elements 120 may be similar to or different from each other, as long as they are electrically coupled to the first conductive element 110. In some embodiments, the first conductive element 110 is hexagonal from a top view perspective.

In some embodiments, a third width W3 of each of the first blocking members 130 is substantially greater than a second width W2 of the corresponding second conductive elements 120. In some embodiments, the first blocking members 130 are separated from each other. In some embodiments, adjacent first blocking members 130 are attached to each other.

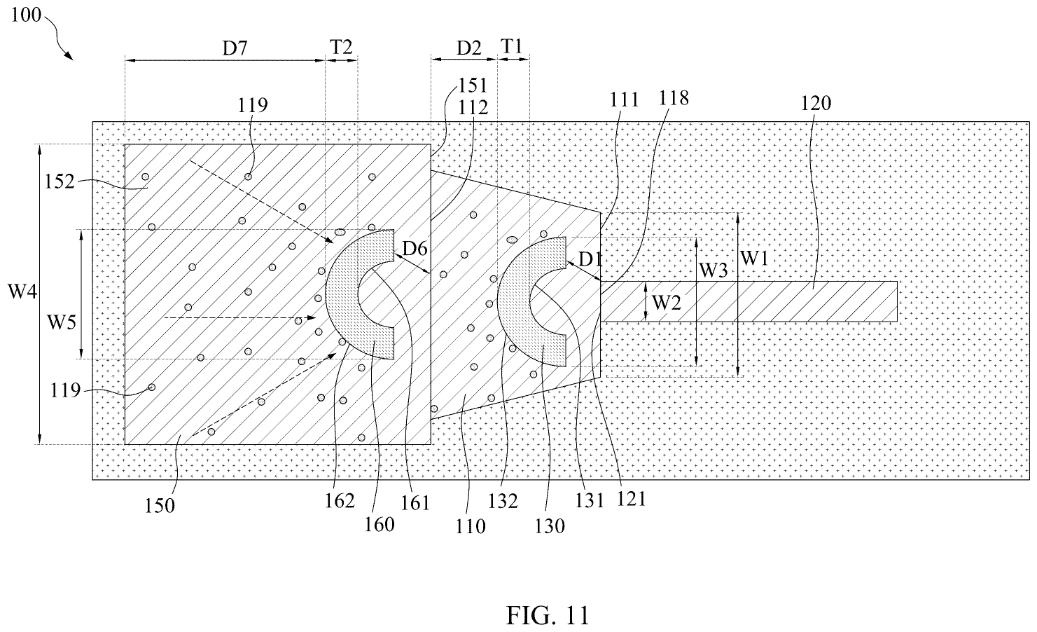

FIG. 11 is a schematic top view illustrating a semiconductor structure according to aspects of the present disclosure in some embodiments. In some embodiments, referring to FIG. 11, the semiconductor structure 100 further includes a third conductive element 150 coupled to a first conductive element 110, and a second blocking member 160 surrounded by the third conductive element 150. The first conductive element 110 is disposed between a second conductive element 120 and the third conductive element 150. In some embodiments, some voids 119 are disposed in the third conductive element 150.

In some embodiments, the third conductive element 150 is mechanically and electrically coupled to a third side 112 of the first conductive element 110. In some embodiments, the third conductive element 150 has a fourth side 151 in contact with the third side 112 of the first conductive element 110 and a fifth side 152 opposite to the fourth side 151. The fifth side 152 is distal from the first conductive element 110.

The third conductive element 150 can be, but is not limited to, round, oval, rectangular, square or another desired shape. A fourth width W4 of the fourth side 151 may be substantially greater than, equal to, or substantially less than a first width W1 of the first side 111. The fourth width W4 may be substantially greater than, equal to, or substantially less than a second width W2 of a second side 121 of the second conductive element. In some embodiments, the fourth width W4 of the fourth side 151 is substantially greater than the first width W1 of the first side 111. In some embodiments, the fourth width W4 of the fourth side 151 is substantially greater than the second width W2 of the second side 121.

The second blocking member 160 may be designed in various shapes or formations. In some embodiments, the second blocking member 160 is configured to ensure electrical coupling between the first conductive element 110 and the third conductive element 150. In some embodiments, the second blocking member 160 includes a second concave portion 161 facing the third side 112 of the first conductive element 110. In some embodiments, the second concave portion 161 faces the second conductive element 120. In some embodiments, the second concave portion 161 faces a first blocking member 130. In some embodiments, the second blocking member 160 further includes a second convex portion 162 disposed opposite to the second concave portion 161.

In some embodiments, a sixth distance D6 between the fourth side 151 and the second blocking member 160 is substantially less than a seventh distance D7 between the fifth side 152 and the second blocking member 160. In some embodiments, the sixth distance D6 is substantially greater than 50 nm. In some embodiments, the sixth distance D6 is also a distance between the second blocking member 160 and the first conductive element 110.

In some embodiments, the second blocking member 160 has a fifth width W5 substantially greater than the second width W2 of the second side 121 of the second conductive element 120. In some embodiments, the second blocking member 160 has a second thickness T2 substantially greater than 50 nm. In some embodiments, the second thickness T2 is constant.

In some embodiments, the second blocking member 160 has a top surface substantially coplanar with a top surface of the third conductive element 150. In some embodiments, the top surface of the second blocking member 160 is substantially coplanar with a top surface of the first conductive element 110 and the first blocking member 130.

In some embodiments, the second blocking member 160 includes dielectric material. In some embodiments, the second blocking member 160 may include a polymer such as PBO, polyimide, BCB, or the like; a nitride such as silicon nitride; an oxide such as silicon oxide, PSG, BSG, BPSG or the like; or a combination thereof. In some embodiments, the second blocking member 160 and a dielectric layer 140 include a same dielectric material. In some embodiments, the second blocking member 160 and the dielectric layer 140 include different dielectric materials. In some embodiments, the second blocking member 160 and the first blocking member 130 include a same dielectric material. In some embodiments, the second blocking member 160 and the first blocking member 130 include different dielectric materials.

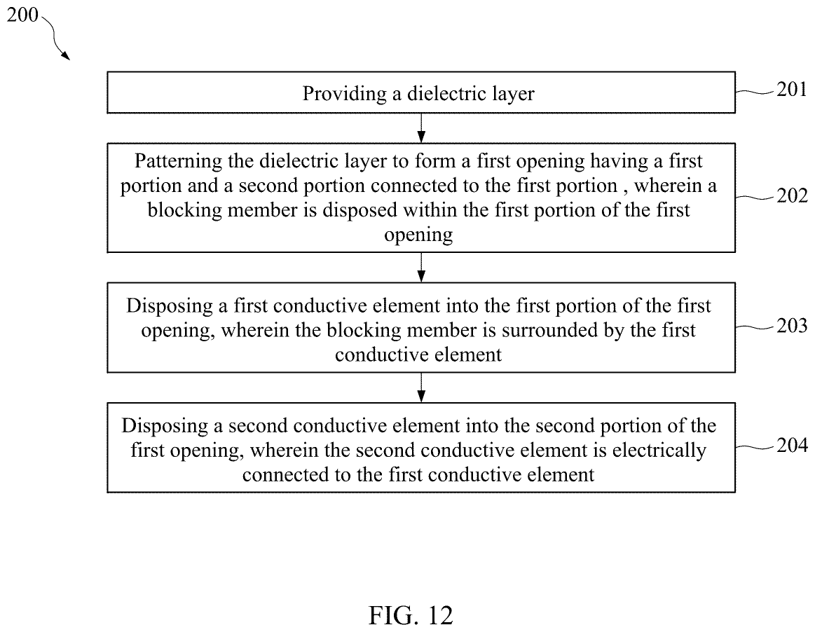

According to some embodiments of the present disclosure, a method for manufacturing a semiconductor structure is disclosed. In some embodiments, the semiconductor structure 100 is fabricated by a method 200. FIG. 12 is a flowchart of the method 200 in accordance with some embodiments. The method 200 includes a number of operations (201 to 204), and descriptions and illustrations are not deemed as a limitation to a sequence of the operations. Additional steps can be provided before, during, and after the operations shown in FIG. 12, and some of the operations described below can be replaced or eliminated in other embodiments of the method 200. An order of the operations may be interchangeable.

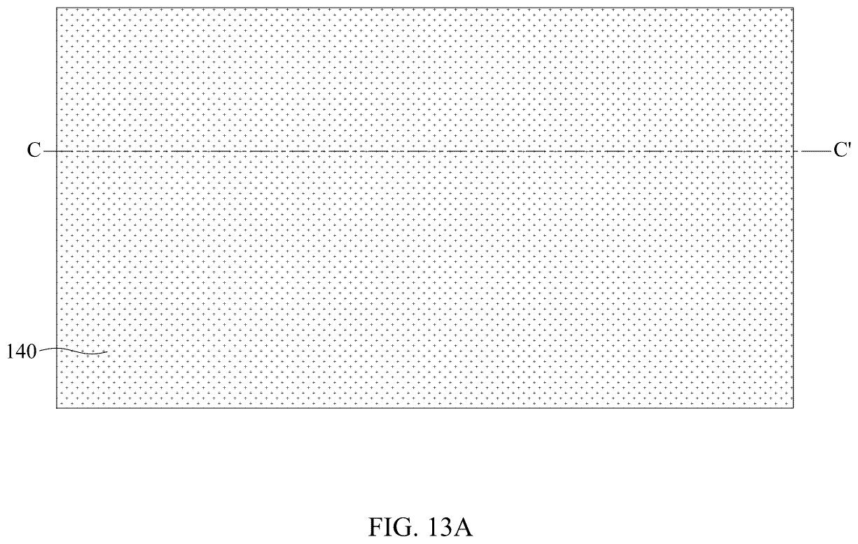

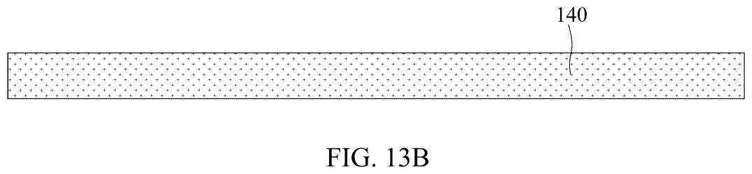

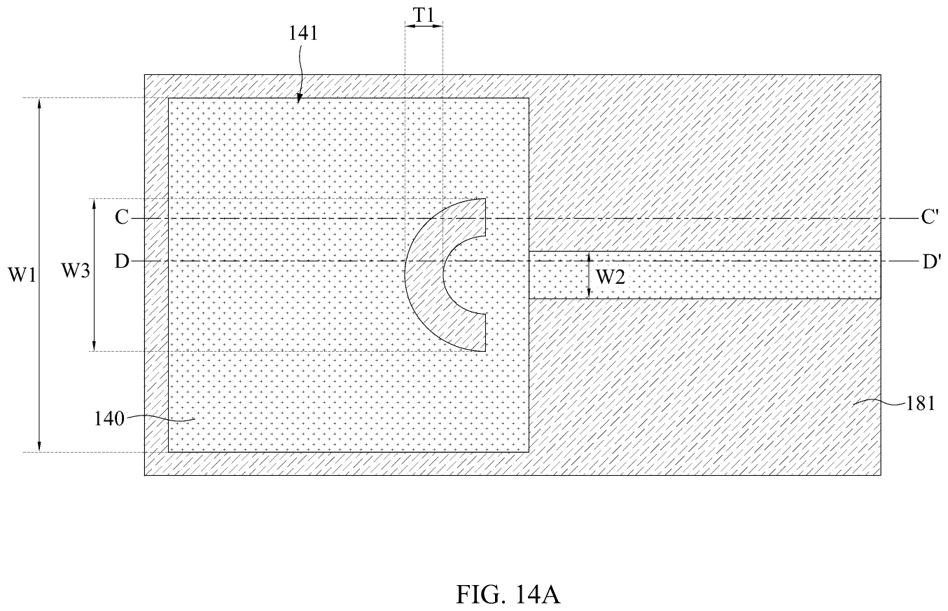

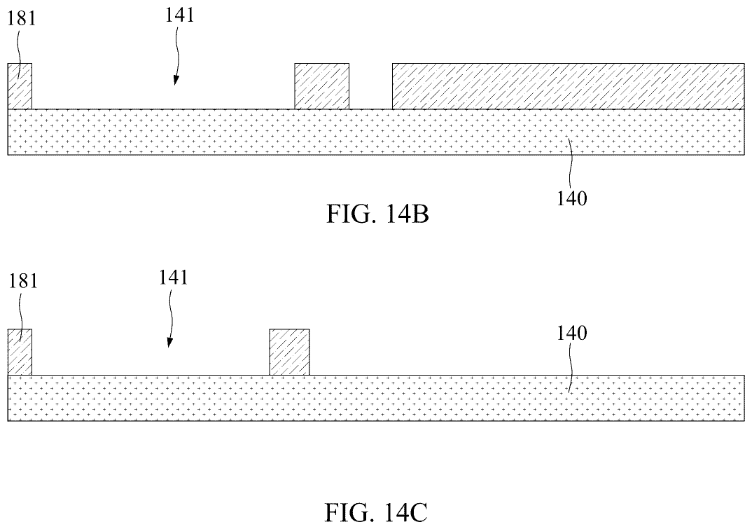

FIGS. 13A, 14A, 15A and 16A are schematic top views of one or more operations of the method 200 for manufacturing a semiconductor structure in accordance with some embodiments of the present disclosure. FIGS. 13B, 14B, 15B and 16B are schematic cross-sectional views taken along a line C-C′ in FIGS. 13A, 14A, 15A and 16A, respectively. FIGS. 14C, 15C and 16C are schematic cross-sectional views taken along a line D-D′ in FIGS. 14A, 15A and 16A, respectively.

The method 200 begins with operation 201. Operation 201 includes providing a dielectric layer. In some embodiments, a dielectric layer 140 is provided as shown in FIGS. 13A and 13B.

The method 200 continues with operation 202. Operation 202 includes patterning the dielectric layer to form a first opening having a first portion and a second portion connected to the first portion, wherein a blocking member is disposed within the first portion of the first opening.

In operation 202, referring to FIGS. 14A, 14B and 14C, a photoresist 181 is formed over the dielectric layer 140. The photoresist 181 may be formed by spin coating and may be exposed to light for patterning. The patterning operation forms the first opening 141 through the photoresist 181 to expose portions of the dielectric layer 140.

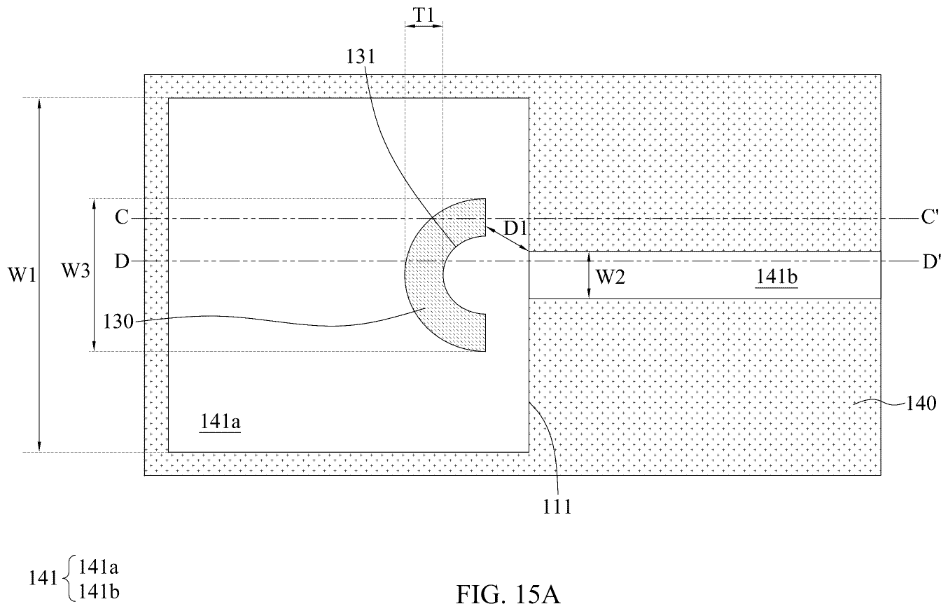

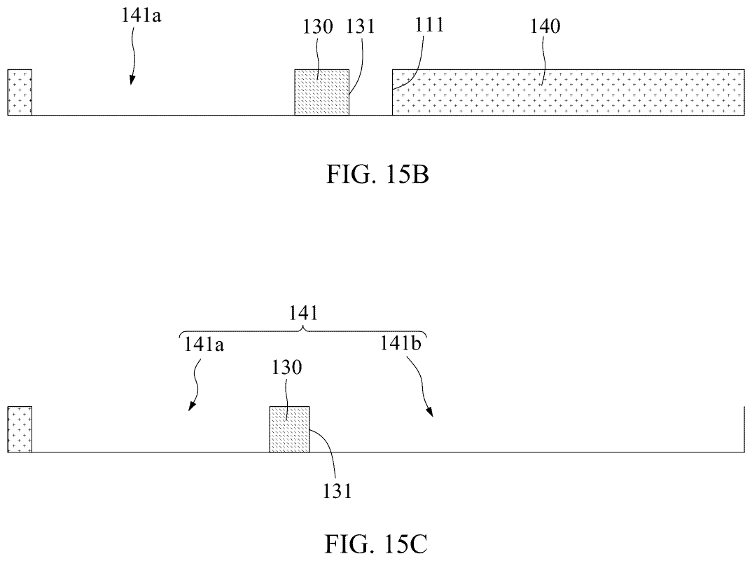

Referring to FIGS. 15A, 15B and 15C, the portions of the dielectric layer 140 exposed by the photoresist 181 are removed to form a blocking member 130, and the first opening 141 having the first portion 141a and the second portion 141b connected to the first portion 141a. In some embodiments, the blocking member 130 is disposed within the first portion 141a of the first opening 141. The thus-formed blocking member 130 was previously a portion of the dielectric layer 140, so that the dielectric layer 140 and the blocking member 130 include a same dielectric material. In some embodiments, the first opening 141 and the blocking member 130 are formed simultaneously. In some embodiments, the blocking member 130 has a convex portion 131 facing the second portion 141b of the first opening 141.

The photoresist 181 is removed after the first opening 141 is formed. The photoresist 181 may be removed by an acceptable washing or stripping process, such as a process using an oxygen plasma or the like.

The method 200 continues with operations 203 and 204. Operation 203 includes disposing a first conductive element into the first portion of the first opening, wherein the blocking member is surrounded by the first conductive element. Operation 204 includes disposing a second conductive element into the second portion of the first opening, wherein the second conductive element is electrically connected to the first conductive element.

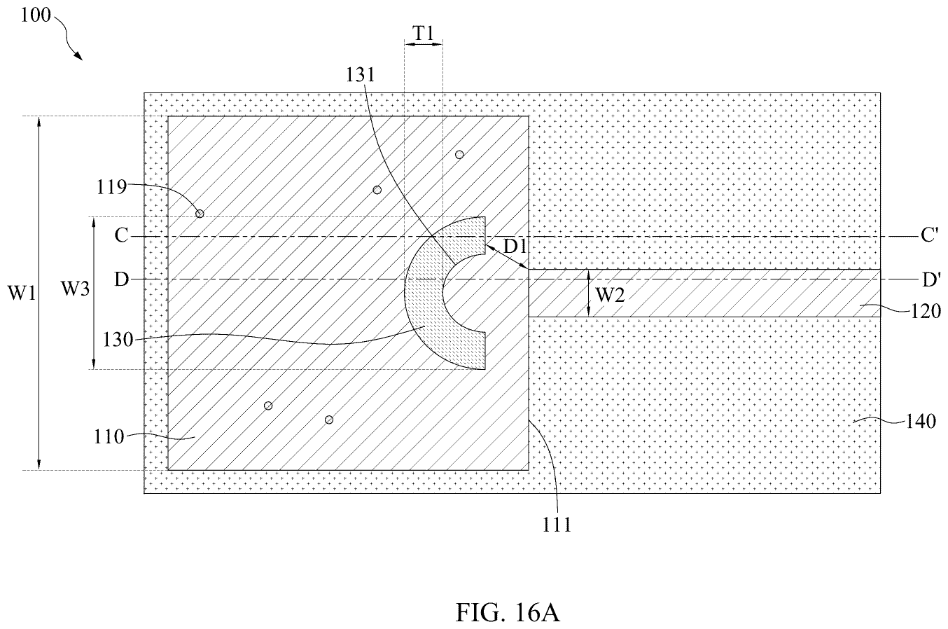

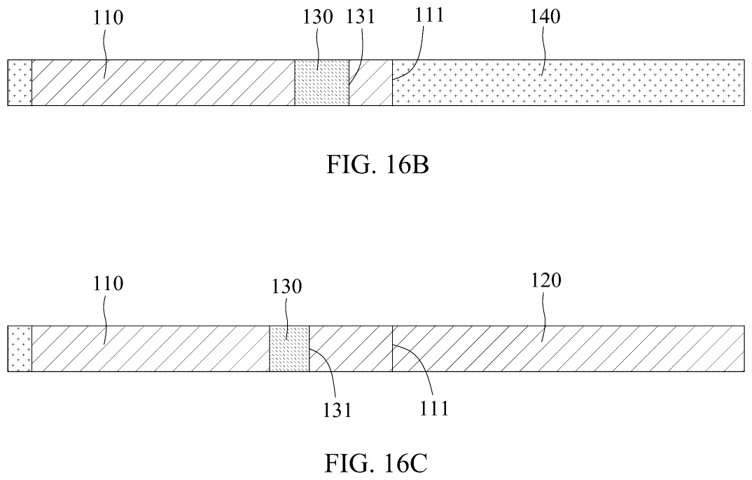

In operation 203, referring to FIGS. 16A, 16B and 16C, the first conductive element 110 is disposed into the first portion 141a of the first opening 141, wherein the blocking member 130 is surrounded by the first conductive element 110. In some embodiments, a first conductive material is deposited into the first portion 141a of the first opening 141. The first conductive material may be deposited by CVD or plating, such as electroplating or electroless plating, or the like. The first conductive material may comprise metal, such as copper, titanium, tungsten, aluminum, or the like. The first conductive element 110 is thus formed in the first portion 141a of the first opening 141.

A planarization operation may be performed to remove excess materials of the first conductive material and level upper surfaces of the first conductive material. After the planarization operation, the first blocking member 130 has a top surface substantially coplanar with a top surface of the first conductive element 110.

In operation 204, still referring to FIGS. 16A, 16B and 16C, a second conductive element 120 is disposed into the second portion 141b of the first opening 141, wherein the second conductive element 120 is electrically connected to the first conductive element 110.

In some embodiments, a second conductive material is deposited into the second portion 141b of the first opening 141 to be electrically connected to the first conductive material. The second conductive material may be deposited by CVD or plating, such as electroplating or electroless plating, or the like. The second conductive material may comprise metal, such as copper, titanium, tungsten, aluminum, or the like. A planarization operation may be performed to remove excess materials of the second conductive material and level upper surfaces of the second conductive material. The second conductive element 120 is thus formed in the second portion 141b of the first opening 141. The second conductive material may be similar to or different from the first conductive material. In some embodiments, the top surface of the first conductive element 110 is level with a top surface of the second conductive element 120.

In some embodiments, the first conductive material is deposited into the first portion 141a and the second portion 141b of the first opening 141 to form the first conductive element 110 and the second conductive element 120. In some embodiments, the first conductive element 110 and the second conductive element 120 are formed simultaneously. In some embodiments, the blocking member 130, the first conductive element 110 and the second conductive element 120 are planarized. In some embodiments, the semiconductor structure 100 is completed.

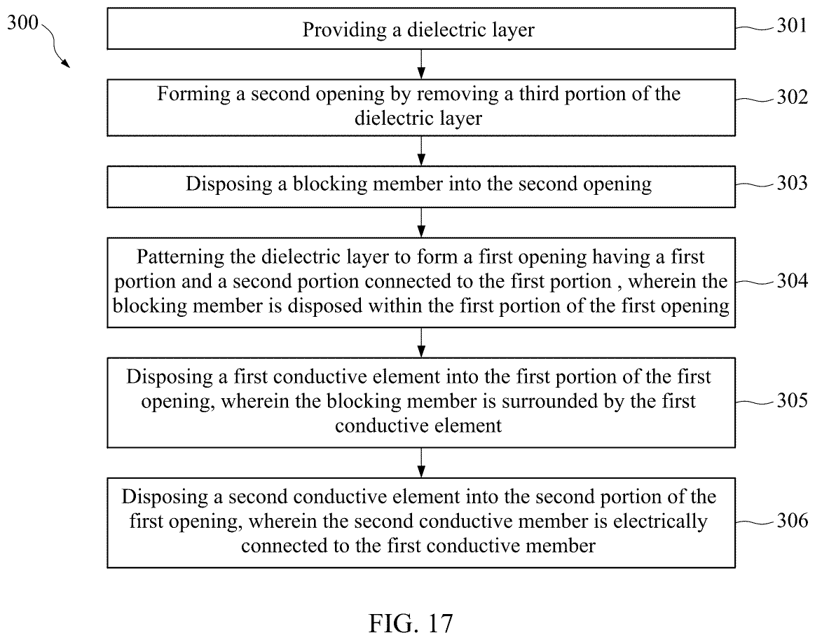

According to some embodiments of the present disclosure, a method for manufacturing a semiconductor structure is disclosed. In some embodiments, the semiconductor structure 100 is fabricated by a method 300. FIG. 17 is a flowchart of the method 300 in accordance with some embodiments. The method 300 includes a number of operations (301 to 306), and descriptions and illustrations are not deemed as a limitation to a sequence of the operations. Additional steps can be provided before, during, and after the operations shown in FIG. 17, and some of the operations described below can be replaced or eliminated in other embodiments of the method 300. An order of the operations may be interchangeable.

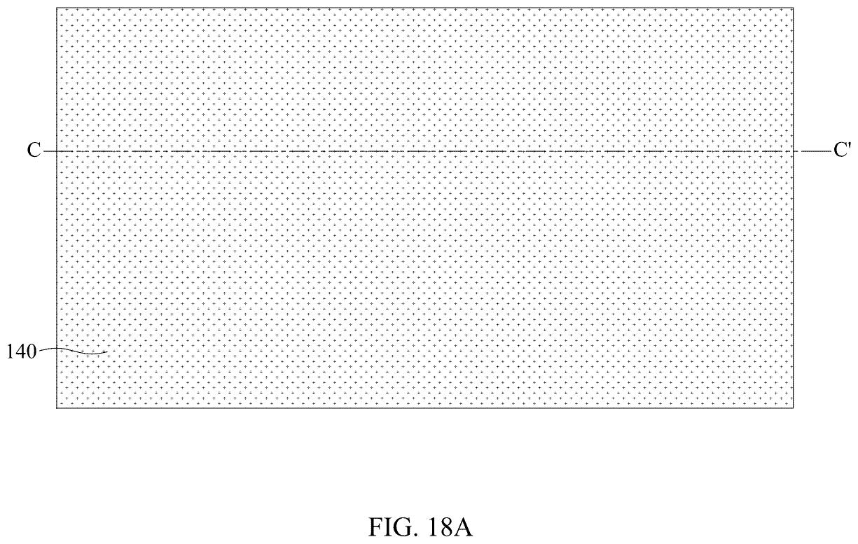

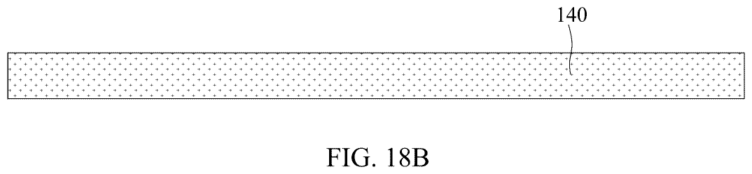

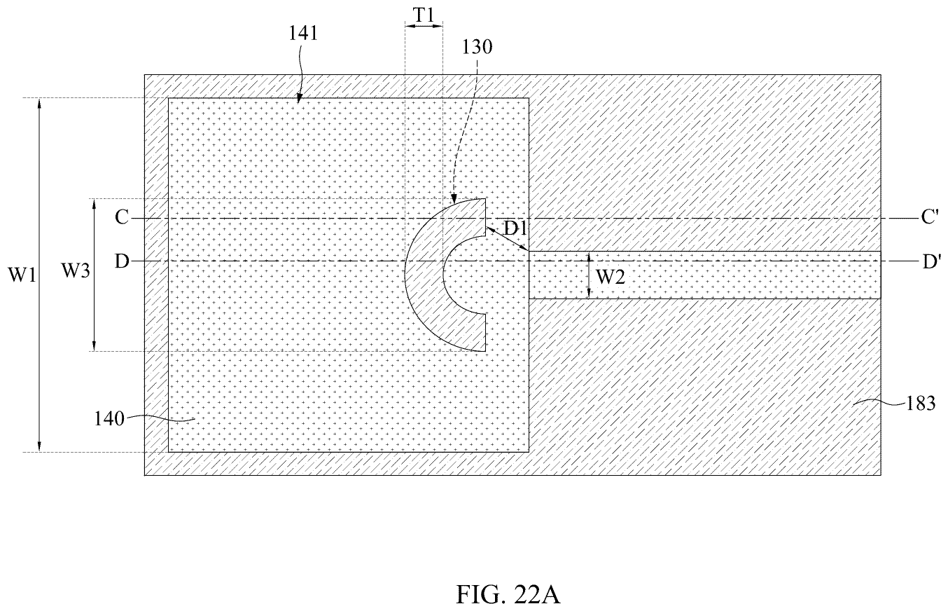

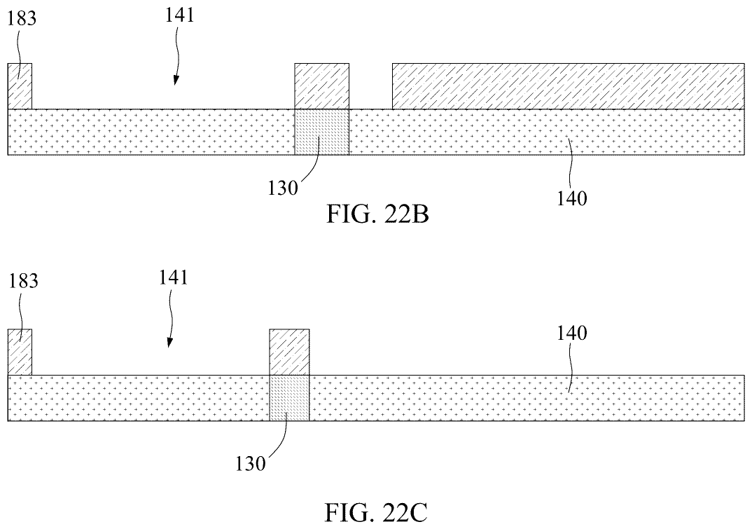

FIGS. 18A, 19A, 20A, 21A, 22A, 23A, 24A and 25A are schematic top views of one or more operations of the method 300 for manufacturing a semiconductor structure in accordance with some embodiments of the present disclosure. FIGS. 18B, 19B, 20B, 21B, 22B, 23B, 24B and 25B are schematic cross-sectional views taken along a line C-C′ in FIGS. 18A, 19A, 20A, 21A, 22A, 23A, and 24A, respectively. FIGS. 22C, 23C, and 24C are schematic cross-sectional views taken along a line D-D′ in FIGS. 22A, 23A, and 24A, respectively.

The method 300 begins with operation 301. Operation 301 includes providing a dielectric layer. In some embodiments, operation 301 of the method 300 is similar to operation 201 of the method 200. In some embodiments, the dielectric layer 140 is provided as shown in FIGS. 18A and 18B. The dielectric layer 140 includes a first dielectric material.

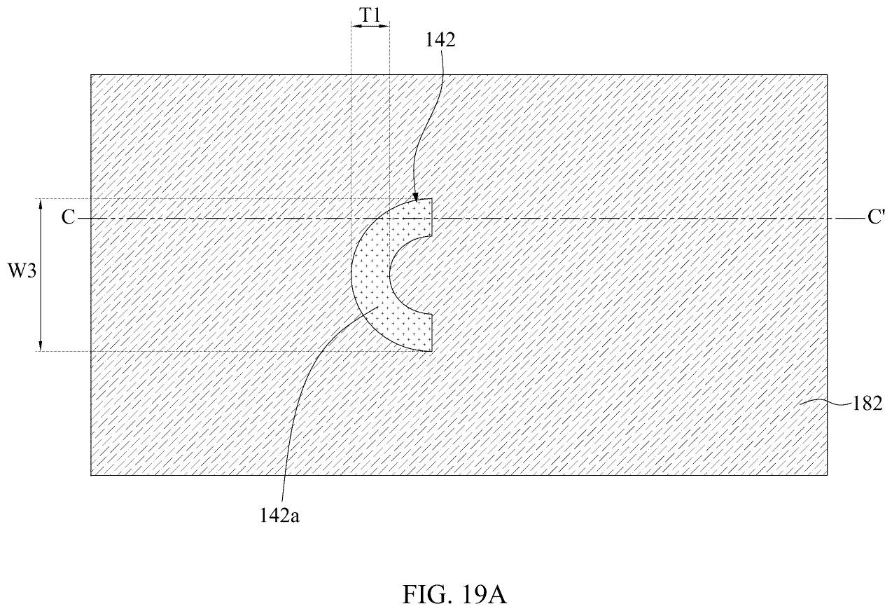

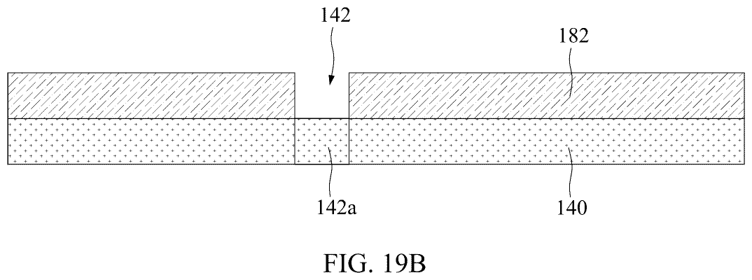

The method 300 continues with operation 302. Operation 302 includes forming a second opening by removing a third portion of the dielectric layer. In operation 302, referring to FIGS. 19A and 19B, a photoresist 182 is formed over the dielectric layer 140. The photoresist 182 may be formed by spin coating and may be exposed to light for patterning. The patterning operation forms the second opening 142 through the photoresist 182 to expose the third portion 142a of the dielectric layer 140 configured to form a blocking member 130.

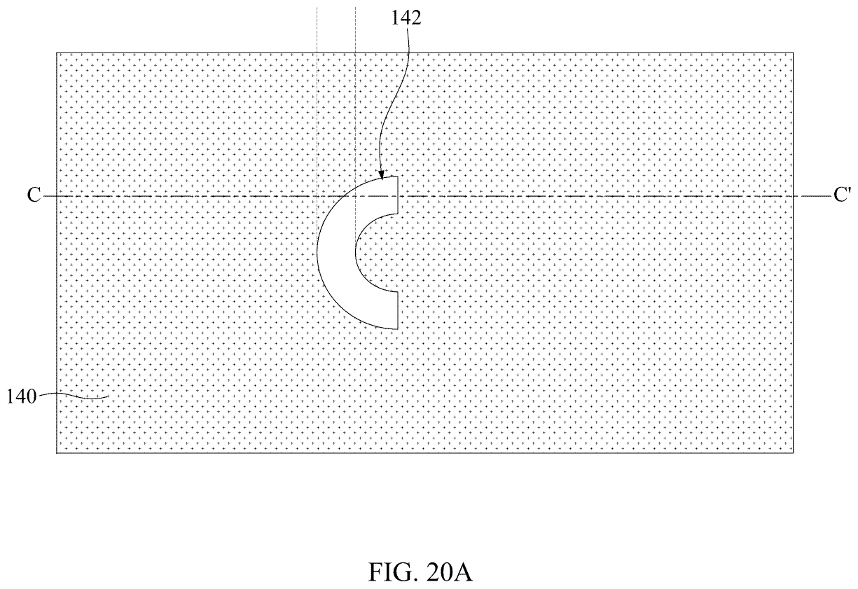

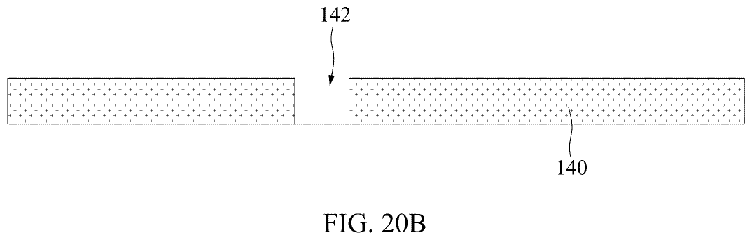

Referring to FIGS. 20A and 20B, the third portion 142a of the dielectric layer 140 exposed by the photoresist 182 is removed to form the second opening 142. The photoresist 182 is removed after the second opening 142 is formed. The photoresist 182 may be removed by an acceptable washing or stripping process, such as a process using an oxygen plasma or the like.

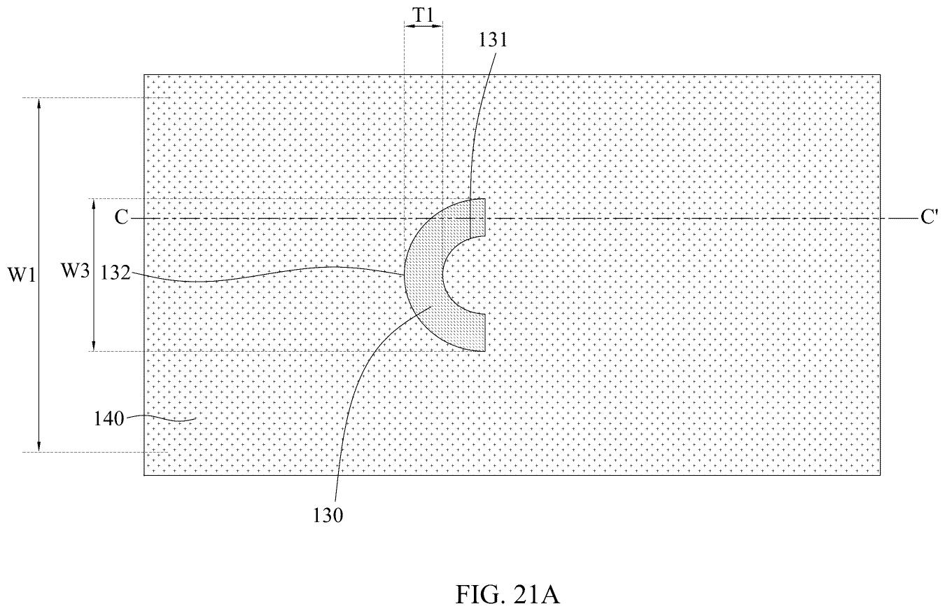

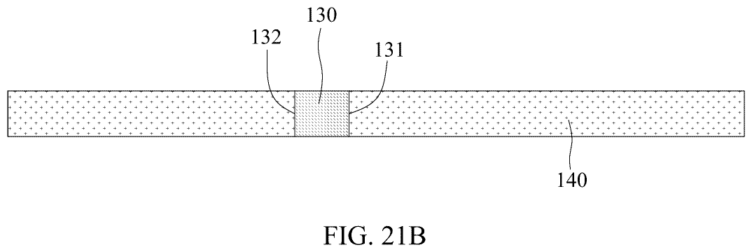

The method 300 continues with operation 303. Operation 303 includes disposing a blocking member into the second opening. In operation 303, referring to FIGS. 21A and 21B, the blocking member 130 is disposed within the second opening 142. In some embodiments, the blocking member 130 includes a second dielectric material different from the first dielectric material of the dielectric layer 140. In some embodiments, the blocking member 130 includes a convex portion 131 and a convex portion 132 opposite to the convex portion 131.

The method 300 continues with operation 304. Operation 304 includes patterning the dielectric layer to form a first opening having a first portion and a second portion connected to the first portion, wherein the blocking member is disposed within the first portion of the first opening. In some embodiments, operation 304 of the method 300 is similar to operation 202 of the method 200.

In operation 304, referring to FIGS. 22A, 22B and 22C, a photoresist 183 is formed over the dielectric layer 140 and the blocking member 130. The photoresist 183 may be formed by spin coating and may be exposed to light for patterning. The patterning operation forms the first opening 141 through the photoresist 183 to expose portions of the dielectric layer 140.

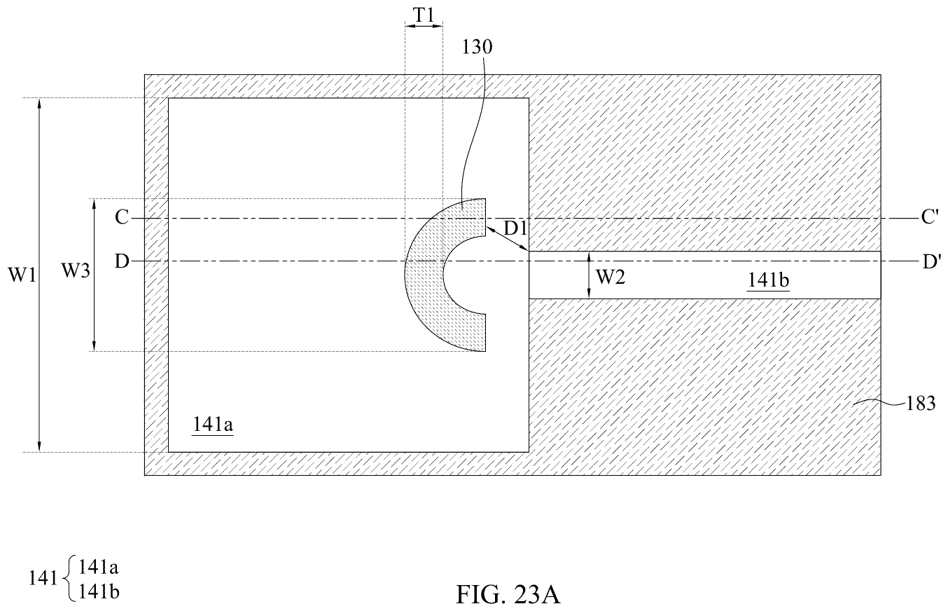

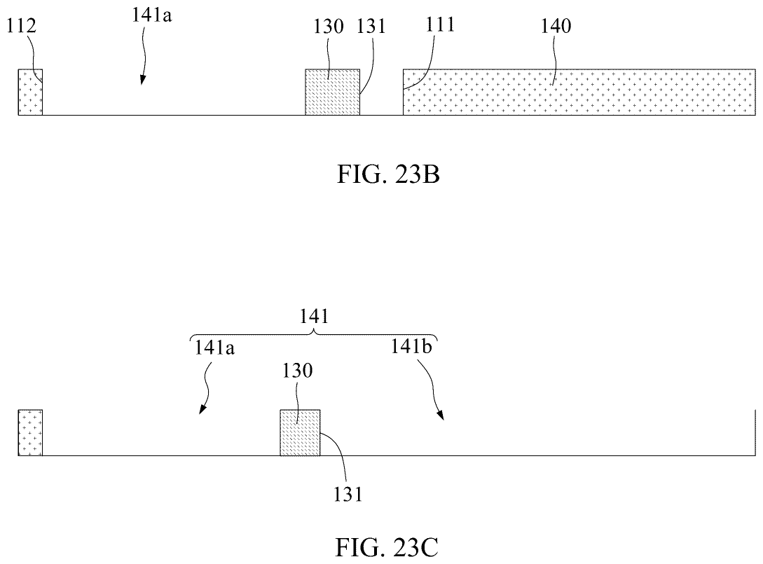

Referring to FIGS. 23A, 23B and 23C, the portions of the dielectric layer 140 exposed by the photoresist 183 are removed to form a first opening 141 having a first portion 141a and a second portion 141b connected to the first portion 141a. In some embodiments, the blocking member 130 is disposed within the first portion 141a of the first opening 141. In some embodiments, the convex portion 131 of the blocking member 130 faces the second portion 141b of the first opening 141.

The photoresist 183 is removed after the first opening 141 is formed. The photoresist 183 may be removed by an acceptable washing or stripping process, such as a process using an oxygen plasma or the like.

The method 200 continues with operations 305 and 306. Operation 305 includes disposing a first conductive element into the first portion of the first opening, wherein the blocking member is surrounded by the first conductive element. In some embodiments, operation 305 of the method 300 is similar to operation 203 of the method 200. Operation 306 includes disposing a second conductive element into the second portion of the first opening, wherein the second conductive element is electrically connected to the first conductive element. In some embodiments, operation 306 of the method 300 is similar to operation 204 of the method 200.

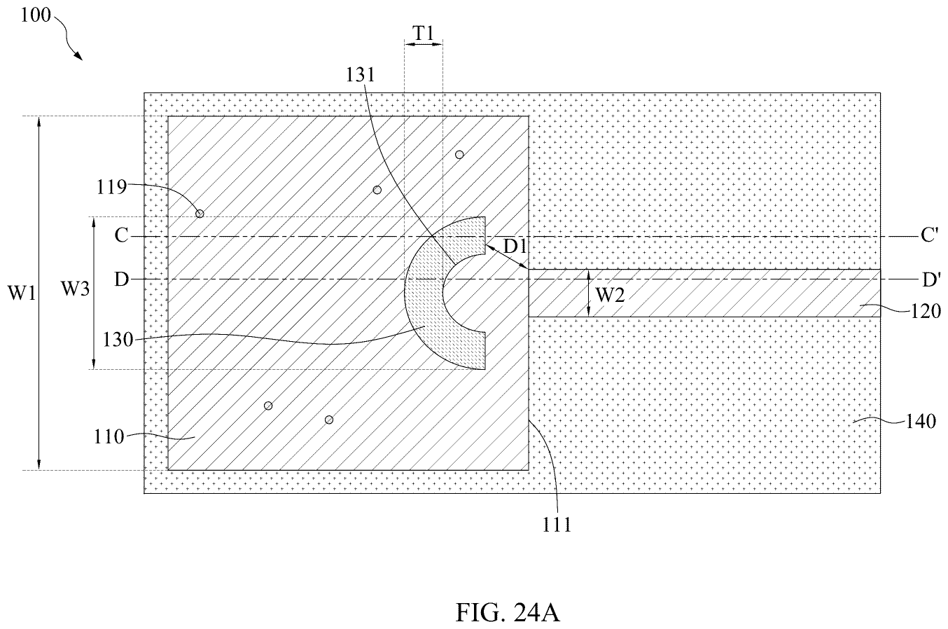

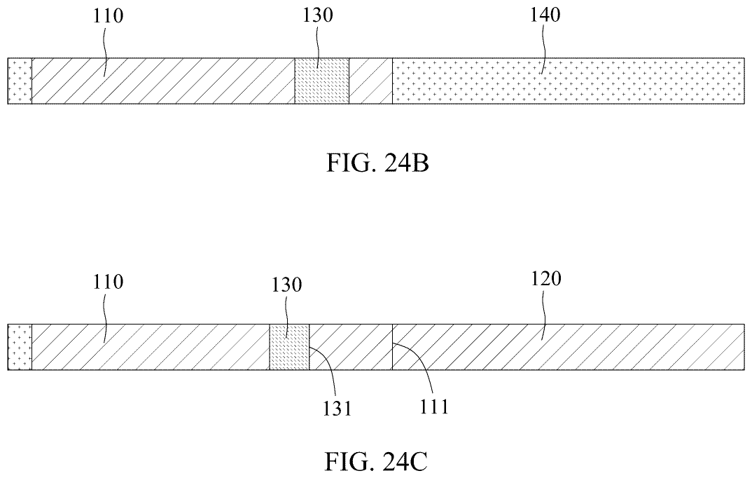

In operation 305, referring to FIGS. 24A, 24B and 24C, the first conductive element 110 is disposed into the first portion 141a of the first opening 141, wherein the blocking member 130 is surrounded by the first conductive element 110.

A planarization operation may be performed to remove excess materials of the first conductive element 110 and level upper surfaces of the first conductive element 110. After the planarization operation, the first blocking member 130 has a top surface substantially coplanar with the top surface of the first conductive element 110.

In operation 306, still referring to FIGS. 24A, 24B and 24C, the second conductive element 120 is disposed into the second portion 141b of the first opening 141, and the second conductive element 120 is electrically connected to the first conductive element 110. In some embodiments, a second conductive material is deposited into the second portion 141b of the first opening 141 to be electrically connected to the first conductive element 110. A planarization operation may be performed to remove the excess materials of the second conductive material and level upper surfaces of the second conductive element 120. The second conductive material may be similar to or different from the first conductive material. In some embodiments, the top surface of the first conductive element 110 is level with the top surface of the second conductive element 120.

In some embodiments, the first conductive material is deposited into the first portion 141a and the second portion 141b of the first opening 141 to form the first conductive element 110 and the second conductive element 120. In some embodiments, the first conductive element 110 and the second conductive element 120 are formed simultaneously. In some embodiments, the semiconductor structure 100 is completed, and the blocking member 130 and the dielectric layer 140 include different dielectric materials.

In accordance with some embodiments of the disclosure, a semiconductor structure includes a first conductive element having a first side, a second conductive element having a second side contacting the first side of the first conductive element, and a blocking member surrounded by the first conductive element and adjacent to the second conductive element. A first width of the first side is substantially greater than a second width of the second side, and at least a portion of the first conductive element is disposed between the second conductive element and the blocking member.

In accordance with some embodiments of the disclosure, a semiconductor structure includes a first blocking member; a first conductive element surrounding the first blocking member; a second conductive element contacting the first conductive element; and a dielectric layer surrounding the first conductive element and the second conductive element. The first blocking member faces the second conductive element, and a first width of the first blocking member is substantially greater than a second width of the second conductive element.

In accordance with some embodiments of the disclosure, a method of manufacturing a semiconductor structure includes providing a dielectric layer; and patterning the dielectric layer to form a first opening having a first portion and a second portion connected to the first portion, wherein a blocking member is disposed within the first portion of the first opening. The method further includes disposing a first conductive element into the first portion of the first opening, wherein the blocking member is surrounded by the first conductive element; and disposing a second conductive element into the second portion of the first opening, wherein the second conductive element is electrically connected to the first conductive element.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first conductive element, having a first side;
a second conductive element, having a second side contacting the first side of the first conductive element; and
a blocking member, surrounded by the first conductive element and adjacent to the second conductive element,
wherein a first width of the first side is substantially greater than a second width of the second side, and at least a portion of the first conductive element is disposed between the second conductive element and the blocking member.

2. The semiconductor structure of claim 1, wherein the first conductive element has a third side opposite to the first side, and a first distance between the first side and the blocking member is substantially less than a second distance between the third side and the blocking member.

3. The semiconductor structure of claim 2, wherein the first distance is substantially greater than 50 nm.

4. The semiconductor structure of claim 1, wherein the blocking member includes a concave portion facing the second side of the second conductive element.

5. The semiconductor structure of claim 1, wherein the blocking member is continuous and integral.

6. The semiconductor structure of claim 1, wherein the blocking member includes segments separated from each other.

7. The semiconductor structure of claim 1, wherein the blocking member has a top surface substantially coplanar with a top surface of the first conductive element.

8. The semiconductor structure of claim 1, wherein the blocking member includes dielectric material.

9. The semiconductor structure of claim 1, wherein the first width is at least 20 times the second width.

10. A semiconductor structure, comprising:
a first blocking member;
a first conductive element surrounding the first blocking member;
a second conductive element contacting the first conductive element; and
a dielectric layer surrounding the first conductive element and the second conductive element,
wherein the first blocking member faces the second conductive element, and a first width of the first blocking member is substantially greater than a second width of the second conductive element.

11. The semiconductor structure of claim 10, wherein the first blocking member has a top surface substantially coplanar with a top surface of the first conductive element.

12. The semiconductor structure of claim 10, further comprising:
a third conductive element coupled to the first conductive element; and
a second blocking member surrounded by the third conductive element having a second convex portion;
wherein the first conductive element is disposed between the second conductive element and the third conductive element, the second convex portion faces the second conductive element, and a third width of the second blocking member is greater than the second width of the second conductive element.

13. The semiconductor structure of claim 12, wherein the second convex portion faces the first blocking member.

14. A method of manufacturing a semiconductor structure, comprising:
providing a dielectric layer;
patterning the dielectric layer to form a first opening having a first portion and a second portion connected to the first portion, wherein a blocking member is disposed within the first portion of the first opening;
disposing a first conductive element into the first portion of the first opening, wherein the blocking member is surrounded by the first conductive element; and
disposing a second conductive element into the second portion of the first opening, wherein the second conductive element is electrically connected to the first conductive element.

15. The method of claim 14, wherein the first opening and the blocking member are formed simultaneously.

16. The method of claim 14, further comprising:
forming a second opening by removing a third portion of the dielectric layer, and
disposing the blocking member into the second opening before patterning the dielectric layer to form the first opening.

17. The method of claim 16, wherein the dielectric layer includes a first material and the blocking member includes a second material different from the first material.

18. The method of claim 14, wherein the first conductive element and the second conductive element are formed simultaneously.

19. The method of claim 14, wherein the blocking member having a convex portion faces the second portion of the first opening.

20. The method of claim 14, further comprising:
planarizing the blocking member, the first conductive element and the second conductive element.
